(19) United States
(12) Patent Application Publication
(10) Pub. No.: US 2025/0223691 A1
(43) Pub. Date: Jul. 10, 2025

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventors: Arito OGAWA, Toyama-shi (JP); Yukinao KAGA, Toyama-shi (JP)

(73) Assignee: KOKUSAI ELECTRIC CORPORATION, Tokyo (JP)

(21) Appl. No.: 19/090,675

(22) Filed: Mar. 26, 2025

Related U.S. Application Data
(63) Continuation of application No. PCT/JP2023/036234, filed on Apr. 10, 2023.

(30) Foreign Application Priority Data
Dec. 23, 2022 (JP) 2022-207376

(51) Int. Cl. C23C 16/44; C23C 16/52

(52) U.S. Cl. CPC C23C 16/4405; C23C 16/52

(57) ABSTRACT

There is provided a technique that includes: (a) processing a substrate in a process container; and (b) a first cleaning of cleaning an inside of the process container, wherein in (b), the act of cleaning is performed with a first cleaning condition that is set based on a thickness of a film formed in the process container in (a).

### CROSS-REFERENCE TO RELATED APPLICATION

This application is a Bypass Continuation Application of PCT International Application No. PCT/JP2023/036234, filed on Oct. 4, 2023 and designating the United States, the international application being based upon and claiming the benefit of priority from Japanese Patent Application No. 2022-207376, filed on Dec. 23, 2022, the entire contents of which are incorporated herein by reference

### TECHNICAL FIELD

The present disclosure relates to a method of processing a substrate, a method of manufacturing a semiconductor device, a recording medium, and a substrate processing apparatus.

### BACKGROUND

In the related art, as a process of manufacturing a semiconductor device, a process of supplying a cleaning gas into a process container of a substrate processing apparatus to clean an inside of the process container may be often carried out.

A time for cleaning may be long, leading to reduced productivity.

### SUMMARY

Some embodiments of the present disclosure provide a technique capable of shortening a time for cleaning.

According to some embodiments of the present disclosure, there is provided a technique that includes: (a) processing the substrate in a process container; and (b) a first cleaning of cleaning an inside of the process container, wherein in (b), the act of cleaning is performed with a first cleaning condition that is set based on a thickness of a film formed in the process container in (a).

### BRIEF DESCRIPTION OF DRAWINGS

The accompanying drawings, which are incorporated in and constitute a part of the specification, illustrate embodiments of the present disclosure.

FIG. 1 is a longitudinal cross-sectional view schematically showing a vertical process furnace of a substrate processing apparatus in some embodiments of the present disclosure.

FIG. 2 is a schematic cross-sectional view taken along line A-A in FIG. 1.

FIG. 3 is a schematic configuration diagram of a controller of a substrate processing apparatus in some embodiments of the present disclosure, in which a control system of the controller is shown in a block diagram.

FIG. 4 is a diagram showing a process flow in some embodiments of the present disclosure.

FIG. 5A is a diagram for explaining an internal state of a reaction tube after a pre-coating step is performed. FIG. 5B is a diagram for explaining an internal state of a reaction tube after a film-forming step is performed. FIG. 5C is a diagram for explaining an internal state of a reaction tube after a first cleaning step is performed. FIG. 5D is a diagram for explaining an internal state of a reaction tube after a second cleaning step is performed.

FIG. 6 is a diagram for explaining a high temperature region and a low temperature region of a substrate processing apparatus in some embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to unnecessarily obscure aspects of the various embodiments.

### Embodiments of Present Disclosure

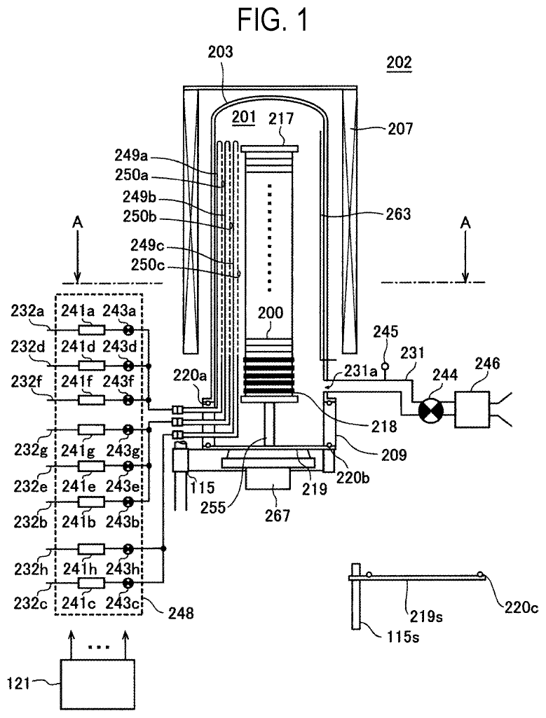

Some embodiments of the present disclosure will now be described mainly with reference to FIGS. 1 to 6. Drawings used in the following description are schematic, and dimensional relationships, ratios, and the like of various components shown in the drawings may not match actual ones. Further, dimensional relationships, ratios, and the like of various components among plural figures may not match one another.

### (1) Configuration of Substrate Processing Apparatus

As shown in FIG. 1, a process furnace 202 includes a heater 207 as a temperature regulator (a heating part). The heater 207 is formed in a cylindrical shape and is supported by a holding plate to be vertically installed. The heater 207 functions as an activator (an exciter) configured to activate (excite) a gas thermally.

A reaction tube 203 is disposed inside the heater 207 to be concentric with the heater 207.

The reaction tube 203 is made of, for example, heat resistant material such as quartz (SiO₂) or silicon carbide (SiC), and is formed in a cylindrical shape with its upper end closed and its lower end opened. A manifold 209 (hereinafter, referred to as MF 209) is disposed to be concentric with the reaction tube 203 under the reaction tube 203. The MF 209 is made of, for example, metal material such as stainless steel (SUS), and is formed in a cylindrical shape with both of its upper and lower ends opened. The upper end of the MF 209 engages with the lower end of the reaction tube 203 to support the reaction tube 203. An O-ring 220a serving as a seal is provided between the MF 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical area of the process container. The process chamber 201 is configured to be capable of accommodating wafers 200 as substrates. The wafers 200 are processed in the process chamber 201.

Nozzles 249a to 249c as first to third suppliers are installed in the process chamber 201 to penetrate a sidewall of the MF 209. The nozzles 249a to 249c are also referred to as first to third nozzles, respectively. The nozzles 249a to 249c are made of, for example, heat resistant material such as SiO₂ or SiC. Gas supply pipes 232a to 232c are connected to the nozzles 249a to 249c, respectively. The nozzles 249a to 249c are different nozzles, and each of the nozzles 249a and 249c is installed adjacent to the nozzle 249b.

Mass flow controllers (MFCs) 241a to 241c, which are flow rate controllers (flow rate control parts), and valves 243a to 243c, which are opening/closing valves, are installed at the gas supply pipes 232a to 232c, respectively, sequentially from the upstream side of a gas flow. Gas supply pipes 232d and 232f are connected to the gas supply pipe 232a at the downstream side of the valve 243a, respectively. Gas supply pipes 232e and 232g are connected to the gas supply pipe 232b at the downstream side of the valve 243b, respectively. A gas supply pipe 232h is connected to the gas supply pipe 232c at the downstream side of the valve 243c. MFCs 241d to 241h and valves 243d to 243e are installed at the gas supply pipes 232d to 232h, respectively, sequentially from the upstream side of a gas flow. The gas supply pipes 232a to 232h are made of, for example, metal material such as SUS.

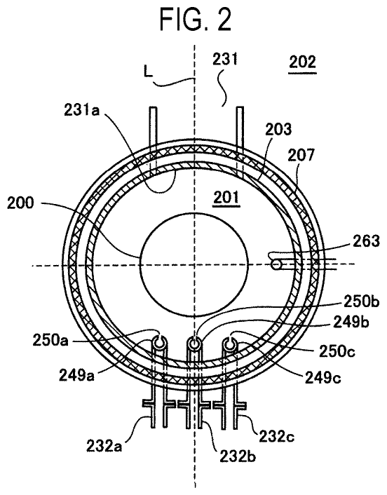

As shown in FIG. 2, each of the nozzles 249a to 249c is installed in an annular space in a plane view between an inner wall of the reaction tube 203 and the wafers 200 to extend upward from a lower side to an upper side of the inner wall of the reaction tube 203, that is, along an arrangement direction of the wafers 200. Specifically, each of the nozzles 249a to 249c is installed in a region horizontally surrounding a wafer arrangement region in which the wafers 200 are arranged at a lateral side of the wafer arrangement region, along the wafer arrangement region. In the plane view, the nozzle 249b is disposed to face an exhaust port 231a described below on a straight line across the centers of the wafers 200 loaded into the process chamber 201. The nozzles 249a and 249c are arranged to sandwich a straight line L passing through the nozzle 249b and the center of the exhaust port 231a from both sides along the inner wall of the reaction tube 203 (outer peripheral sides of the wafers 200). The straight line L is also a straight line passing through the nozzle 249a and the centers of the wafers 200. That is, the nozzle 249c may be installed on the side opposite to the nozzle 249b with the straight line L interposed therebetween. The nozzles 249a and 249c are arranged in a line-symmetry relationship with the straight line L as an axis of symmetry. Gas supply holes 250a to 250c configured to supply a gas are formed on the side surfaces of the nozzles 249a to 249c, respectively. Each of the gas supply holes 250a to 250c is opened to oppose (face) the exhaust port 231a in the plane view, which enables the gas to be supplied toward the wafers 200. A plurality of gas supply holes 250a to 250c are formed from the lower side to the upper side of the reaction tube 203.

A first process gas as a precursor gas is supplied from the gas supply pipe 232a into the process chamber 201 via the MFC 241a, the valve 243a, and the nozzle 249a. For example, a metal element-containing gas, a silicon (Si)-containing gas, or the like may be used as the first process gas.

A second process gas as a reaction gas is supplied from the gas supply pipe 232b into the process chamber 201 via the MFC 241b, the valve 243b, and the nozzle 249b. For example, a nitriding gas or the like may be used as the second process gas.

A third process gas as a reducing gas is supplied from the gas supply pipe 232c into the process chamber 201 via the MFC 241c, the valve 243c, and the nozzle 249c. For example, a Si- and hydrogen (H)-containing gas or the like may be used as the third process gas.

A first cleaning gas (hereinafter, referred to as a first CLN gas) is supplied from the gas supply pipe 232d into the process chamber 201 via the MFC 241d, the valve 243d, the gas supply pipe 232a, and the nozzle 249a. For example, a gas with a selectivity may be used as the first CLN gas. Further, a gas that may be active (react with a film) in a high-temperature environment, for example, 400 to 600 degrees C., and perform etching at a high temperature can be used as the first CLN gas. Herein, “with a selectivity” means that there is a removal speed ratio when etching a film, and a film that is a target of cleaning (hereinafter referred to as CLN) is selectively etched. In the present disclosure, notation of a numerical range such as “400 to 600 degrees C.” means that a lower limit value and an upper limit value are included in that range. Therefore, for example, “400 to 600 degrees C.” means “400 degrees C. or higher and 600 degrees C. or lower.” The same applies to other numerical ranges.

A second cleaning gas (hereinafter, referred to as a second CLN gas) is supplied from the gas supply pipe 232e into the process chamber 201 via the MFC 241e, the valve 243e, the gas supply pipe 232b, and the nozzle 249b. A gas without a selectivity may be used as the second CLN gas. In addition, a gas that may be active in a low-temperature environment, for example, at 200 to 400 degrees C., and perform etching even at a low temperature may be used as the second CLN gas.

An inert gas is supplied from the gas supply pipes 232f to 232h into the process chamber 201 via the MFCs 241f to 241h, the valves 243f to 243h, the gas supply pipes 232f to 232h, and the nozzles 249a to 249c, respectively. The inert gas acts as a purge gas, a carrier gas, a dilution gas, or the like.

A first process gas supply system mainly includes the gas supply pipe 232a, the MFC 241a, and the valve 243a. A second process gas supply system mainly includes the gas supply pipe 232b, the MFC 241b, and the valve 243b. A third process gas supply system mainly includes the gas supply pipe 232c, the MFC 241c, and the valve 243c. A first CLN gas supply system mainly includes the gas supply pipe 232d, the MFC 241d, and the valve 243d. A second CLN gas supply system mainly includes the gas supply pipe 232e, the MFC 241e, and the valve 243e. An inert gas supply system mainly includes the gas supply pipes 232f to 232h, the MFCs 241f to 241h, and the valves 243f to 243h.

One or the entirety of the above-described various supply systems may be constituted as an integrated supply system 248 in which the valves 243a to 243h, the MFCs 241a to 241h, and so on are integrated. The integrated supply system 248 is connected to each of the gas supply pipes 232a to 232h, and is configured such that operations of supplying various substances (various gases) into the gas supply pipes 232a to 232h, that is, opening/closing operations of the valves 243a to 243h, flow rate regulating operations by the MFCs 241a to 241h, and the like, are controlled by a controller 121 which will be described later. The integrated supply system 248 is constituted as an integral or detachable integrated unit, and may be attached to or detached from the gas supply pipes 232a to 232h and the like on an integrated unit basis, such that maintenance, replacement, extension, and the like of the integrated supply system 248 may be performed on an integrated unit basis.

The exhaust port 231a configured to exhaust an internal atmosphere of the process chamber 201 is installed below the sidewall of the reaction tube 203. As shown in FIG. 2, in the plane view, the exhaust port 231a is installed at a position opposing (facing) the nozzles 249a to 249c (the gas supply holes 250a to 250c) with the wafers 200 interposed therebetween. The exhaust port 231a may be installed from the lower side to the upper side of the sidewall of the reaction tube 203, that is, along the wafer arrangement region. An exhaust pipe 231 is connected to the exhaust port 231a.

A vacuum pump 246 as a vacuum exhauster, is connected to the exhaust pipe 231 via a pressure sensor 245, which is a pressure detector (pressure detection part) configured to detect an internal pressure of the process chamber 201, and an auto pressure controller (APC) valve 244, which is a pressure regulator (pressure regulation part). The APC valve 244 is configured to be capable of performing or stopping a vacuum exhausting operation in the process chamber 201 by opening or closing the valve while the vacuum pump 246 is actuated, and is also configured to be capable of regulating the internal pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219 (hereinafter, referred to as a cap 219), which serves as a furnace opening lid configured to be capable of hermetically sealing a lower end opening of the MF 209, is installed under the MF 209. The cap 219 is made of, for example, a metal material such as SUS, and is formed in a disc shape. An O-ring 220b, which is a seal making contact with the lower end of the MF 209, is installed on an upper surface of the cap 219. A rotator 267 configured to rotate a boat 217, which will be described later, is installed under the cap 219. A rotary shaft 255 of the rotator 267 is connected to the boat 217 through the cap 219. The rotator 267 is configured to rotate the wafers 200 by rotating the boat 217. The cap 219 is configured to be vertically moved up or down by a boat elevator 115 (hereinafter, referred to as an elevator 115) which is an elevator installed outside the reaction tube 203. The boat elevator 115 is constituted as a transfer apparatus (transfer mechanism) configured to loads or unload (transfer) the wafers 200 into or out of the process chamber 201 by moving the cap 219 up or down.

A shutter 219s, which serves as a furnace opening lid configured to be capable of hermetically sealing a lower end opening of the MF 209 in a state where the cap 219 is lowered and the boat 217 is unloaded from the process chamber 201, is installed under the MF 209. The shutter 219s is made of, for example, a metal material such as SUS, and is formed in a disc shape. An O-ring 220c, which is a seal making contact with the lower end of the MF 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as SiO₂ or SiC. Heat insulating plates 218 made of, for example, a heat resistant material such as SiO₂ or SiC are installed in multiple stages at a lower side of the boat 217.

A temperature sensor 263 serving as a temperature detector is installed in the reaction tube 203. Based on temperature information detected by the temperature sensor 263, a state of supplying electric power to the heater 207 is regulated such that a temperature distribution in the process chamber 201 becomes a desired temperature distribution. The temperature sensor 263 is installed along the inner wall of the reaction tube 203.

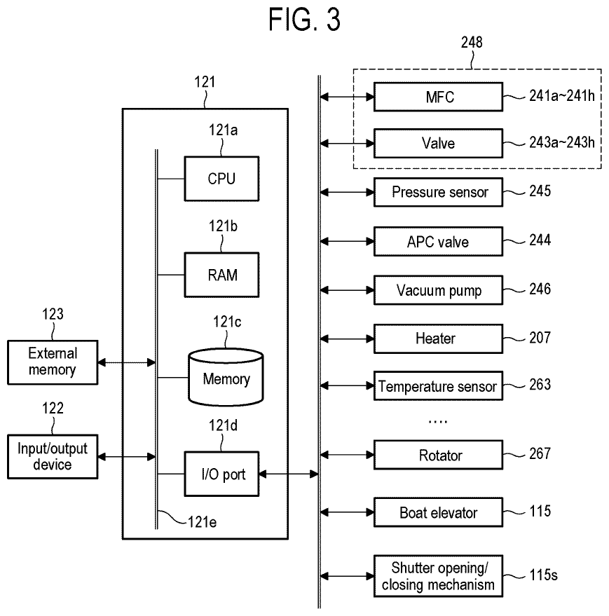

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 constituted as, e.g., a touch panel or the like, is connected to the controller 121. Further, an external memory 123 may be connected to the controller 121.

The memory 121c is constituted by, for example, a flash memory, a hard disk drive (HDD), a solid state drive (SSD), or the like. A control program to control operations of a substrate processing apparatus, a process recipe in which sequences and conditions of substrate processing to be described later are written, etc. are readably recorded and stored in the memory 121c. The process recipe functions as a program that is combined to cause, by the controller 121, the substrate processing apparatus to execute each sequence in the substrate processing, which will be described later, to obtain an expected result. Hereinafter, the process recipe and the control program may be generally and simply referred to as a “program.” Further, the process recipe may be simply referred to as a “recipe.” When the term “program” is used herein, it may indicate a case of including the recipe, a case of including the control program, or a case of including both the recipe and the control program. The RAM 121b is configured as a memory area (work area) in which programs or data read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opening/closing mechanism 115s, and so on.

The CPU 121a is configured to be capable of reading and executing the control program from the memory 121c. The CPU 121a is also configured to be capable of reading the recipe from the memory 121c according to an input of an operation command from the input/output device 122. The CPU 121a is configured to be capable of controlling the flow rate regulating operation of various kinds of materials (gases) by the MFCs 241a to 241h, the opening/closing operation of the valves 243a to 243h, the opening/closing operation of the APC valve 244, the pressure regulating operation performed by the APC valve 244 based on the pressure sensor 245, the actuating and stopping operation of the vacuum pump 246, the temperature regulating operation performed by the heater 207 based on the temperature sensor 263, the operation of rotating the boat 217 and adjusting the rotation speed of the boat 217 with the rotator 267, the operation of moving the boat 217 up or down by the boat elevator 115, the opening/closing operation of the shutter 219s by the shutter opening/closing mechanism 115s, and so on, according to contents of the read recipe.

The controller 121 may be configured by installing, on the computer, the aforementioned program recorded and stored in the external memory 123. Examples of the external memory 123 may include a magnetic disk such as a HDD, an optical disc such as a CD, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Further, the program may be provided to the computer by using communication means or unit such as the Internet or a dedicated line, instead of using the external memory 123.

### (2) Substrate Processing Process

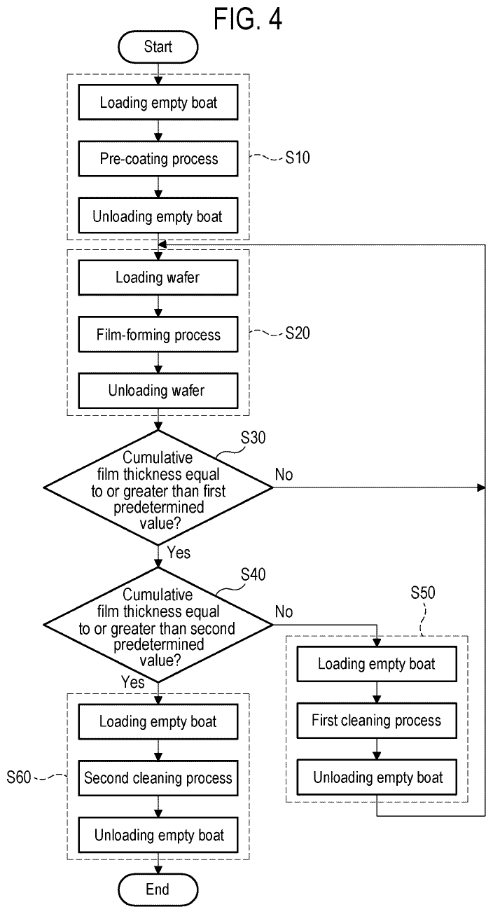

As a process of manufacturing a semiconductor device by using the above-described substrate processing apparatus, an example of a series of processing sequences including a film-forming process of forming a film on a wafer 200 will be described mainly with reference to FIGS. 4 to 6. In the following description, an operation of each component constituting the substrate processing apparatus is controlled by the controller 121.

### Pre-Coating Step, Step S10

First, a pre-coating step of forming a film inside the process container before performing a film-forming step will be described.

### Empty Boat Loading

In this step, in a state where an empty boat 217 is loaded in the process container, a process is performed to form a film on surfaces of components in the reaction tube 203 inside the process container, such as the inner wall of the reaction tube 203, outer surfaces of the nozzles 249a to 249c, inner surfaces of the nozzles 249a to 249c, an inner surface of the MF 209, a surface of the boat 217, and the upper surface of the cap 219. The process may be performed with the boat 217 unloaded. In other words, the inside of the process container is pre-coated.

### Pre-Coating Process (Film-Forming Process)

### Supply of First Process Gas, Step S11

In this step, a first process gas is supplied into the process chamber 201. Specifically, the valve 243a is opened to allow the first process gas to flow through the gas supply pipe 232a. A flow rate of the first process gas is regulated by the MFC 241a. The first process gas is supplied into the process chamber 201 via the nozzle 249a and is exhausted via the exhaust port 231a. At the same time, the valve 243f is opened to allow an inert gas to flow through the gas supply pipe 232a. In addition, at this time, to prevent the first process gas from entering the nozzles 249b and 249c, the valves 243g and 243h may be opened to allow an inert gas to flow through the gas supply pipes 232b and 232c, respectively.

Herein, for example, a metal element-containing gas may be used as the first process gas. For example, a titanium (Ti)-containing gas, aluminum (Al)-containing gas, zirconium (Zr)-containing gas, hafnium (Hf)-containing gas, molybdenum (Mo)-containing gas, gallium (Ga)-containing gas, or indium (In)-containing gas may be used as the metal element-containing gas. For example, a titanium tetrachloride (TiCl₄) gas may be used as the Ti-containing gas. Further, in addition to the metal element-containing gas, for example, a Si-containing gas may be used as the first process gas. One or more of these gases may be used as the first process gas.

A nitrogen (N₂) gas and a rare gas such as an argon (Ar) gas, a helium (He) gas, a neon (Ne) gas, or a xenon (Xe) gas may be used as the inert gas. One or more of these gases may be used as the inert gas. The same applies to each step to be described later.

### Purging, Step S12

After a predetermined time elapses since the supply of the first process gas starts, the valve 243a is closed to stop the supply of the first process gas into the process chamber 201. Then, the inside of the process chamber 201 is vacuum-exhausted to remove a gas and the like remaining in the process chamber 201 from the inside of the process chamber 201 (purging). At this time, the valves 243f, 243g, and 243h are opened to allow an inert gas to be supplied into the process chamber 201. The inert gas acts as a purge gas.

### Supply of Second Process Gas, Step S13

Next, a second process gas is supplied into the process chamber 201. Specifically, the valve 243b is opened to allow the second process gas to flow through the gas supply pipe 232b. A flow rate of the second process gas is regulated by the MFC 241b. The second process gas is supplied into the process chamber 201 via the nozzle 249b and is exhausted via the exhaust port 231a. At the same time, the valve 243g is opened to allow an inert gas to flow through the gas supply pipe 232b. In addition, at this time, to prevent the second process gas from entering the nozzles 249a and 249c, the valves 243f and 243h may be opened to allow an inert gas to flow through the gas supply pipes 232a and 232c, respectively.

Herein, for example, a nitriding gas or the like is used as the second process gas. For example, a hydrogen nitride-based gas such as an ammonia (NH₃) gas, a diazene (N₂H₂) gas, a hydrazine (N₂H₄) gas, or a N₃H₈ gas may be used as the nitriding gas. One or more of these gases may be used as the second process gas.

### Purging, Step S14

After a predetermined time elapses since the supply of the second process gas starts, the valve 243b is closed to stop the supply of the second process gas into the process chamber 201. Then, a gas and the like remaining in the process chamber 201 are removed from the inside of the process chamber 201 (purging) according to the same processing procedures as the purging in step S12.

### Performing Predetermined Number of Times, Step S15

By performing a cycle a predetermined number of times (X times, where X is an integer of 1 or 2 or more), the cycle including performing the above-described steps S11 to S14 non-simultaneously, i.e., without synchronization, a film with a predetermined composition and a predetermined thickness may be formed on a component in the process container. Herein, for example, a titanium nitride (TiN) film is formed.

### Supply of Third Process Gas, Step S16

Then, after performing the cycle the predetermined number of times, the cycle including performing the above-described steps S11 to S14 in this order, a third process gas is supplied into the process chamber 201. Specifically, the valve 243c is opened to allow the third process gas to flow through the gas supply pipe 232c. A flow rate of the third process gas is regulated by the MFC 241c, and the third process gas is supplied into the process chamber 201 via the nozzle 249c and is exhausted via the exhaust port 231a. At the same time, the valve 243h is opened to allow an inert gas to flow through the gas supply pipe 232c. In addition, at this time, to prevent the third process gas from entering the nozzles 249a and 249b, the valves 243f and 243g may be opened to allow an inert gas to flow through the gas supply pipes 232a and 232b, respectively.

Herein, for example, a Si- and H-containing gas may be used as the third process gas. For example, a silane-based gas such as a monosilane (SiH₄) gas, a disilane (Si₂H₆) gas, or a trisilane (Si₃H₈) gas may be used as the Si- and H-containing gas. One or more of these gases may be used as the third process gas.

### Purging, Step S17

After a predetermined time elapses since the supply of the third process gas starts, the valve 243c is closed to stop the supply of the third process gas into the process chamber 201. Then, a gas and the like remaining in the process chamber 201 are removed from the inside of the process chamber 201 (purging) according to the same processing procedures as the purging in step S12.

### Performing Predetermined Number of Times

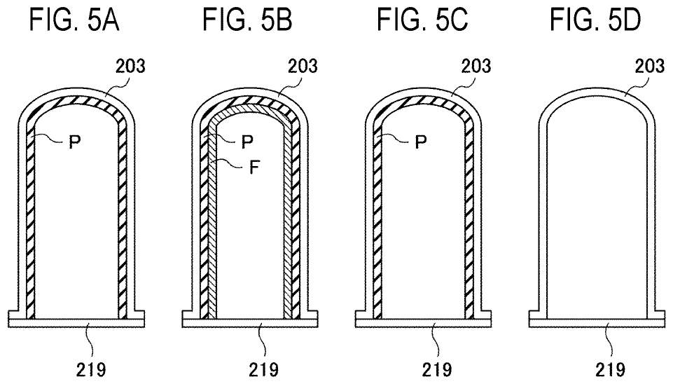

By performing a cycle a predetermined number of times (Y times, where Y is an integer of 1 or 2 or more), the cycle including performing the above-described steps S15 to S17 non-simultaneously, i.e., without synchronization, a film P with a predetermined thickness is formed on a surface of the inside of the reaction tube 203, as a component in the process container, for example, as shown in FIG. 5A. Herein, for example, a titanium silicon nitride (TiSiN) film is formed as the film P.

The process is completed through above series of operations. By the above-described pre-coating process, a film different from the film formed on the wafer 200 in a film-forming step S20, which will be described later, is formed as the film P on the surface of the inside of the reaction tube 203. This allows etching using a selectivity to be performed. In addition, by forming the film P, an adhesion with the inner wall, etc. of the reaction tube 203 is improved, making it difficult for the film to be peeled off from the inner wall, etc. In addition, a surface roughness of an initial film of the film P may be reduced. In addition, the above-described pre-coating process makes it possible to suppress a film thickness drop phenomenon during film formation. In addition, the above-described pre-coating process makes it possible to adjust an environment and a state in the process container before the next film-forming process.

A supply order or a supply timing of the first process gas, the second process gas, and the third process gas in the above-described pre-coating process are not limited to the above-described order or timing.

### Empty Boat Unloading

After the pre-coating process is completed, the cap 219 is lowered by the elevator 115, and the lower end of the MF 209 is opened. Then, an empty boat 217 is unloaded from the lower end of the MF 209 to the outside of the reaction tube 203. After the boat is unloaded, the shutter 219s is moved, and the lower end opening of the MF 209 is sealed by the shutter 219s via the O-ring 220c.

### Film-Forming Step, Step S20

Next, a film-forming step of loading the wafer 200 into the process furnace 202 and forming a film on the wafer 200 will be described. That is, in this step, a film-forming step of processing the wafer 200 in the process chamber is performed.

When the term “wafer” is used in the present disclosure, it may refer to “a wafer itself” or “a stacked body of a wafer and certain layers or films formed on a surface of the wafer.” When the phrase “a surface of a wafer” is used in the present disclosure, it may refer to “a surface of a wafer itself” or “a surface of a certain layer and the like formed on a wafer.” When the expression “a certain layer is formed on a wafer” is used in the present disclosure, it may mean that “a certain layer is formed directly on a surface of a wafer itself” or that “a certain layer is formed on a layer and the like formed on a wafer.” When the term “substrate” is used in the present disclosure, it may be synonymous with the term “wafer.”

### Wafer Loading

When the boat 217 is charged with a plurality of wafers 200, as shown in FIG. 1, the boat 217 charged with the plurality of wafers 200 is lifted up by the elevator 115 to be loaded into the process chamber 201. In this state, the cap 219 may close the lower end opening of the reaction tube 203 via the O-ring 220b.

The inside of the process chamber 201, that is, a space where the wafers 200 are placed, is vacuum-exhausted by the vacuum pump 246 to reach a desired pressure (degree of vacuum). At this time, the internal pressure of the process chamber 201 is measured by the pressure sensor 245, and the APC valve 244 is feedback-controlled based on the measured pressure information (pressure regulation). Further, the inside of the process chamber 201 is heated by the heater 207 so as to reach a desired temperature. At this time, a state of supplying an electrical power supplied to the heater 207 is controlled based on the temperature information detected by the temperature sensor 263 such that a temperature distribution in the process chamber 201 becomes a desired temperature distribution (temperature regulation). Further, the rotation of the wafers 200 by the rotator 267 is started. The exhaust of the inside of the process chamber 201, and the heating and rotation of the wafers 200 are continuously performed at least until the processing on the wafers 200 is completed.

### [Film-Forming Process] (Supply of First Process Gas, Step S21)

In this step, a first process gas is supplied to the wafer 200 in the process chamber 201. Specifically, the valve 243a is opened to allow the first process gas to flow through the gas supply pipe 232a. A flow rate of the first process gas is regulated by the MFC 241a. The first process gas is supplied into the process chamber 201 via the nozzle 249a and is exhausted via the exhaust port 231a. At the same time, the valve 243f is opened to allow an inert gas to flow through the gas supply pipe 232a. In addition, at this time, to prevent the first process gas from entering the nozzles 249b and 249c, the valves 243g and 243h may be opened to allow an inert gas to flow through the gas supply pipes 232b and 232c, respectively.

### Purging, Step S22

After a predetermined time elapses since the supply of the first process gas starts, the valve 243a is closed to stop the supply of the first process gas into the process chamber 201. Then, a gas and the like remaining in the process chamber 201 are removed from the inside of the process chamber 201 (purging) according to the same processing procedures as the purging in step S12.

### Supply of Second Process Gas, Step S23

Next, a second process gas is supplied to the wafer 200 in the process chamber 201. Specifically, the valve 243b is opened to allow the second process gas to flow through the gas supply pipe 232b. A flow rate of the second process gas is regulated by the MFC 241b. The second process gas is supplied into the process chamber 201 via the nozzle 249b and is exhausted via the exhaust port 231a. At the same time, the valve 243g is opened to allow an inert gas to flow through the gas supply pipe 232b. In addition, at this time, to prevent the second process gas from entering the nozzles 249a and 249c, the valves 243f and 243h may be opened to allow an inert gas to flow through the gas supply pipes 232a and 232c, respectively.

### Purging, Step S24

After a predetermined time elapses since the supply of the second process gas starts, the valve 243b is closed to stop the supply of the second process gas into the process chamber 201. Then, a gas and the like remaining in the process chamber 201 are removed from the inside of the process chamber 201 (purging) according to the same processing procedures as the purging in step S12.

### Performing Predetermined Number of Times

By performing a cycle a predetermined number of times (n times, where n is an integer of 1 or 2 or more), the cycle including performing the above-described steps S21 to S24 non-simultaneously, i.e., without synchronization, a film with a predetermined composition and a predetermined thickness may be formed on the wafer 200.

Herein, for example, a nitride film is formed as the film formed on the wafer 200. For example, a metal element-containing nitride film is formed as the nitride film. For example, a TiN film, an aluminum nitride (AlN) film, a gallium nitride (GaN) film, an indium nitride (InN) film, a molybdenum nitride (MoN) film, etc. are formed as the metal element-containing nitride film. In addition, for example, a silicon nitride (SiN) film, etc. are formed as the nitride film.

### After-Purge and Returning to Atmospheric Pressure

After the formation of the film is completed, an inert gas acting as a purge gas is supplied into the process chamber 201 from each of the nozzles 249a to 249c and is exhausted via the exhaust port 231a. Thus, the inside of the process chamber 201 is purged and a gas or reaction by-products remaining in the process chamber 201 are removed from the inside of the process chamber 201 (after-purge). Thereafter, the internal atmosphere of the process chamber 201 is substituted with an inert gas (inert gas substitution) and the internal pressure of the process chamber 201 is returned to a normal pressure (returning to atmospheric pressure).

### Wafer Unloading

The cap 219 is lowered by the elevator 115, and the lower end of the MF 209 is opened. Then, the processed wafers 200 supported by the boat 217 are unloaded from the lower end of the MF 209 to the outside of the reaction tube 203. After the boat unloading, the shutter 219s is moved and the lower end opening of the MF 209 is sealed by the shutter 219s via the O-ring 220c. The processed wafers 200 are unloaded from the reaction tube 203 and are then discharged from the boat 217.

When the above-described film-forming process is performed, a film is formed on the surfaces of the components inside the process container, that is, the reaction tube 203, such as the inner wall of the reaction tube 203, the outer surfaces of the nozzles 249a to 249c, the inner surfaces of the nozzles 249a to 249c, the inner surface of the MF 209, the surface of the boat 217, and the upper surface of the cap 219, and is accumulated as a deposit. That is, as shown in FIG. 5B, a deposited film F is formed on the surface inside the reaction tube 203 on which the film P in FIG. 5A is formed. In a case where an amount of deposits, that is, a cumulative film thickness of the deposited film F, becomes too large, the deposited film F may be peeled off, and an amount of particles generated may increase. For this reason, before the deposited film F is peeled off, a CLN process may be performed to entirely remove the deposited film F deposited inside the reaction tube 203 and form a film inside the reaction tube 203 from which the deposited film F is entirely removed. In this case, the productivity may decrease because it takes a long time to perform the CLN process and to form the film.

In the embodiments of the present disclosure, a first cleaning process (hereinafter, referred to as a first CLN process) or a second cleaning process (hereinafter, referred to as a second CLN process) is performed according to the thickness of the deposited film F formed in the reaction tube 203 (also referred to as a cumulative film thickness or an amount of deposits). This makes it possible to shorten the time for CLN and improve the productivity. Herein, the cumulative film thickness is a thickness of the deposited film F deposited by the film-forming process, and when the CLN process is performed, it is calculated by subtracting the amount etched by the CLN process. That is, the cumulative film thickness of the film formed in the reaction tube 203 is estimated, for example, by pre-storing the film thickness of the film formed on the wafer 200 by one film-forming process and the amount etched by the CLN process and counting a number of times each process is performed each time the film formation is performed. In addition, the cumulative film thickness may be an actual measurement value.

### First Determination Step, Step S30

First, it is determined whether or not the cumulative film thickness is equal to or greater than a first predetermined value. If the cumulative film thickness is smaller than the first predetermined value, the process returns to step S20, where the film-forming process is performed on the next wafer 200. Further, if the cumulative film thickness is equal to or greater than the first predetermined value, the next second determination step S40 is performed. Herein, the first predetermined value is, for example, 0.015 to 1.0 μm.

For example, the controller 121 stores the film thickness of the film formed on the wafer 200 by one film-forming step S20 and the film thickness of the film etched by one first CLN step and estimates the cumulative film thickness each time the film-forming step S20 is performed. That is, in this step, the controller 121 counts a number of times the film-forming process is performed, which is a number of times the film-forming step S20 is performed, and estimates that the cumulative film thickness is equal to or greater than the first predetermined value when the number of consecutively performed film-forming steps S20 reaches a predetermined number of times.

The cumulative film thickness may be calculated based on at least one selected from the group of a processing time, a flow rate of a gas used in the film-forming process, and an internal pressure of the process chamber 201.

### Second Determination Step, Step S40

Next, it is determined whether or not the cumulative film thickness is equal to or greater than a second predetermined value that is greater than the first predetermined value. If the cumulative film thickness is smaller than the second predetermined value, that is, equal to or greater than the first predetermined value and smaller than the second predetermined value, the first CLN step S50 to be described later is performed. Further, if the cumulative film thickness is equal to or greater than the second predetermined value, the second CLN step S60 to be described later is performed. Herein, the second predetermined value is a film thickness at which cracks may occur in the deposited film F and/or the film P inside the reaction tube 203, and is, for example, 0.2 to 3 μm.

### First CLN Step, Step S50

In this step, an empty boat 217 is loaded into the process chamber 201, and a first CLN process is performed to remove at least a portion of the deposited film F deposited in the process container in a short time. That is, CLN is performed in the process container. The first CLN process may also be referred to as a simple CLN.

### Empty Boat Loading

The shutter 219s is moved by the shutter opening/closing mechanism 115s, and the lower end opening of the MF 209 is opened. After that, the empty boat 217, i.e., the boat 217 not charged with the wafers 200, is lifted up by the elevator 115 and is loaded into the process chamber 201. In this state, the cap 219 seals the lower end of the MF 209 via the O-ring 220b. The first CLN process may be performed with the boat 217 unloaded.

After the empty boat 217 is loaded into the process chamber 201, the inside of the process chamber 201 is vacuum-exhausted by the vacuum pump 246 so that the inside of the process chamber 201 is at a desired pressure. Further, the inside of the process chamber 201 is heated by the heater 207 to reach a desired temperature. In addition, the rotator 267 starts to rotate the boat 217. The operation of the vacuum pump 246, the heating of the inside of the process chamber 201, and the rotation of the boat 217 are continuously performed at least until this step is completed. The boat 217 may not be rotated. A processing pressure in this step is made to be higher than a processing pressure in the second CLN step S60 to be described later. Further, a processing temperature in this step is made to be higher than a processing temperature in the second CLN step S60 to be described later.

In the present disclosure, the processing temperature means the temperature of the wafer 200 or the internal temperature of the process chamber 201, and the processing pressure means the internal pressure of the process chamber 201. Further, the processing time means a time during which the process continues. The same applies to the following description.

### [First CLN Process] (Supply of First CLN Gas)

First, a first CLN gas is supplied into the process chamber 201. Specifically, the valve 243d is opened to allow the first CLN gas to flow through the gas supply pipe 232a. A flow rate of the first CLN gas is regulated by the MFC 241d. The first CLN gas is supplied into the process chamber 201 via the nozzle 249a and is exhausted via the exhaust pipe 231. At the same time, the valve 243f is opened to allow an inert gas to flow through the gas supply pipe 232a. In addition, at this time, to prevent the first CLN gas from entering the nozzles 249b and 249c, the valves 243g and 243h may be opened to allow an inert gas to flow through the gas supply pipes 232b and 232c, respectively.

For example, a nitrogen trifluoride (NF₃) gas, a fluorine (F₂) gas, a chlorine (Cl₂) gas, a hydrogen fluoride (HF) gas, or the like may be used as the first CLN gas. One or more of these gases may be used as the first CLN gas.

After a predetermined time elapses and the first CLN process in the process chamber 201 is completed, the valve 243d is closed to stop the supply of the first CLN gas into the process chamber 201. That is, the first CLN gas is supplied, for a short period of time, into the reaction tube 203 where a target film of the first CLN is formed. Then, the inside of the process chamber 201 is purged (purging) according to the same processing procedures as the above-described purging. After that, the internal atmosphere of the process chamber 201 is substituted with an inert gas (inert gas substitution).

The first CLN process is completed through the above-described series of operations.

In this step, based on the cumulative film thickness of the deposited film F, a first CLN condition is set and CLN is performed. That is, in a case where the thickness of the deposited film F deposited in the reaction tube 203 is equal to or greater than the first predetermined value and smaller than the second predetermined value, the first CLN process is performed based on the first CLN condition. Herein, the first CLN condition is a condition for etching the deposited film F of an amount equal to or less than an amount of the deposited film F corresponding to the thickness of the deposited film F deposited in the reaction tube 203. For example, the first CLN condition is a condition for etching the deposited film F formed in the film-forming step S20 and not etching the film P formed in the pre-coating step S10.

Specifically, for example, in a case where the deposited film F as a target of CLN is a TiN film, a NF₃ gas is used as the first CLN gas. As a result, as shown in FIG. 5C, at least a portion of the deposited film F may be etched so as to leave the film P formed in the pre-coating step.

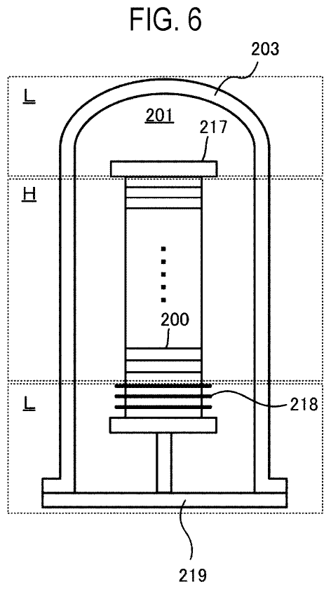

In addition, a gas that etches a film formed in a high temperature region H shown in FIG. 6 is used as the first CLN gas. In this step, the film formed in the high temperature region H of the process chamber 201 may be etched. That is, a portion of the film formed in the high temperature region H whose cumulative film thickness is larger than a cumulative film thickness of a film formed in a low temperature region L shown in FIG. 6, may be etched. The high temperature region H may also be called a product region where the wafers 200 which are product substrates are arranged.

In addition, a processing pressure in this step is made to be higher than a processing pressure in a second CLN step S60 to be described later. This allows the film formed in the high temperature region H of the reaction tube 203 to be etched. That is, a portion of the film formed in the high temperature region H whose cumulative film thickness is larger than a cumulative film thickness of the film formed in the low temperature region L, may be etched.

In addition, a processing temperature in this step is made to be higher than the processing temperature in the second CLN step S60 to be described later. This allows a difference between the temperature in the high temperature region H and the temperature in the low temperature region L other than the high temperature region H. That is, the temperature in the high temperature region H and the temperature in the low temperature region L may be made non-uniform. That is, a portion of the film formed in the high temperature region H whose cumulative film thickness is larger than the cumulative film thickness of the film formed in the low temperature region L, may be etched.

In addition, a supply time of the first CLN gas in this step is made to be shorter than a supply time of the second CLN gas in the second CLN step S60 to be described later. This allows the film formed in the high temperature region H to be etched in this step. That is, a portion of the film formed in the high temperature region H whose cumulative film thickness is larger than the cumulative film thickness of the film formed in the low temperature region L, may be etched.

In addition, a gas with a selectivity, as described above, is used as the first CLN gas. This allows at least a portion of the deposited film F, which is the target film of CLN formed in the reaction tube 203, to be etched, and the film P to be left unetched. That is, the deposited film F formed in the film-forming step S20 may be etched, and the film P formed in the pre-coating step S10 may be left unetched. This prevents SiO₂ on the inner wall, etc. of the reaction tube 203 from being exposed. That is, by setting the first CLN condition based on the cumulative film thickness of the deposited film F and performing CLN, a predetermined amount of film may be left in the reaction tube 203.

Herein, for example, in an impermeable film such as a TiN film, heat from the heater 207 is not easily transferred to the wafer 200. In a case where the film thickness of the film formed on the inner wall, etc. of the process container changes significantly, the internal temperature of the reaction tube 203 may differ between the substrate processing immediately after CLN and a substrate processing other than that. Therefore, in this step, the film formed in the reaction tube 203 is left to maintain an impermeable state in the reaction tube 203, thereby reducing temperature changes in the reaction tube 203 and facilitating temperature control.

The thickness of the film etched in this step may be the same as the thickness of the deposited film F formed in the film-forming step S20 or may be larger or smaller than the thickness of the deposited film F formed in the film-forming step S20. In either case, after this step is performed, a film with a thickness smaller than a predetermined value is formed in the reaction tube 203. The film P may be left at all times. Further, an impermeable film may be left.

In addition, when forming, for example, a TiN film in the film-forming step S20, abnormal growth nuclei grow along with crystal growth of TiN. In this step, the abnormal growth nuclei formed on the surface of the TiN film in the reaction tube 203 are removed (etched). As a result, the surface of the TiN film formed in the reaction tube 203 is etched and flattened.

### Empty Boat Unloading

After the first CLN process is completed, the cap 219 is lowered by the elevator 115, and the lower end of the MF 209 is opened. Then, the empty boat 217 is unloaded from the lower end of the MF 209 to the outside of the reaction tube 203. After the boat unloading, the shutter 219s is moved, and the lower end opening of the MF 209 is sealed by the shutter 219s via the O-ring 220c. Then, the boat 217 is charged with a plurality of next wafers 200 and the above-described film-forming S20 is performed.

### Second CLN Step, S60

In this step, an empty boat 217 is loaded into the process chamber 201, and a second CLN process is performed to remove the deposited film F and the film P deposited on the inner wall, etc. of the reaction tube 203 in a longer time than the above-described first CLN process.

### Empty Boat Loading

The shutter 219s is moved by the shutter opening/closing mechanism 115s, and the lower end opening of the MF 209 is opened (shutter opening). After that, the empty boat 217, i.e., the boat 217 not charged with the wafers 200, is lifted up by the elevator 115 and is loaded into the process chamber 201. In this state, the cap 219 seals the lower end of the MF 209 via the O-ring 220b. The second CLN process may be performed with the boat 217 unloaded.

After the empty boat 217 is loaded into the process chamber 201, the inside of the process chamber 201 is vacuum-exhausted by the vacuum pump 246 so that the inside of the process chamber 201 reaches a desired pressure. In addition, the inside of the process chamber 201 is heated by the heater 207 to reach a desired temperature. In addition, the rotator 267 starts to rotate the boat 217. The operation of the vacuum pump 246, the heating of the inside of the process chamber 201, and the rotation of the boat 217 are continuously performed at least until the CLN step S50 is completed. The boat 217 may not be rotated. The processing pressure in this step is made to be lower than the processing pressure in the above-described first CLN step S50. Further, the processing temperature in this step is made to be lower than the processing temperature in the above-described first CLN step S50.

### Second CLN Process

### Supply of Second CLN Gas

First, a second CLN gas is supplied into the process chamber 201. Specifically, the valve 243e is opened to allow the second CLN gas to flow through the gas supply pipe 232b. A flow rate of the second CLN gas is regulated by the MFC 241e. The second CLN gas is supplied into the process chamber 201 via the nozzle 249b and is exhausted via the exhaust pipe 231. At the same time, the valve 243g is opened to allow an inert gas to flow through the gas supply pipe 232b. In addition, at this time, to prevent the second CLN gas from entering the nozzles 249a and 249c, the valves 243f and 243h may be opened to allow an inert gas to flow through the gas supply pipes 232a and 232c, respectively.

For example, at least one or more selected from the group of a fluorine (F₂) gas, a nitrogen trifluoride (NF₃) gas, a chlorine trifluoride (ClF₃) gas, a chlorine (Cl₂) gas, a boron trichloride (BCl₃) gas, and a bromine (Br₂) gas may be used as the second CLN gas. A gas different from the first CLN gas may be used.

After a predetermined time elapses and the second CLN process in the process chamber 201 is completed, the valve 243e is closed to stop the supply of the second CLN gas into the process chamber 201. That is, the second CLN gas is supplied into the reaction tube 203 where the target film of the second CLN is formed, for a longer time than the supply time of the first CLN gas. Then, the inside of the process chamber 201 is purged according to the same processing procedures as the above-described purging (purging). After that, the internal atmosphere of the process chamber 201 is substituted with an inert gas (inert gas substitution).

The second CLN process is completed through above series of operations.

In this step, based on the cumulative thickness of the deposited film F, a second CLN condition is set and CLN is performed. That is, when the thickness of the deposited film F deposited in the reaction tube 203 is equal to or greater than a second predetermined value that is greater than the first predetermined value, the second CLN process is performed based on the second CLN condition. Herein, the second CLN condition is a condition for etching a film with a thickness equal to or greater than the thickness of the deposited film F deposited in the reaction tube 203 and is a condition for etching the film P formed in the reaction tube 203 as well. That is, by performing the second CLN based on the second CLN condition, the film P formed in the reaction tube 203 is also etched.

That is, by performing CLN with the second CLN conditions set based on the cumulative film thickness of the deposited film F, the deposited film F and film P formed in the reaction tube 203 may be etched as shown in FIG. 5D.

A gas that etches a film formed in the entire reaction tube 203 including the low temperature region L of the reaction tube 203 shown in FIG. 6 is used as the second CLN gas. Herein, the low temperature region L refers to a region where the wafer 200, which is the product substrate, is not placed, and means a heat insulating region, periphery of a lid of the reaction tube 203, etc. That is, in this step, the film formed in the entire reaction tube 203 including the low temperature region L of the reaction tube 203 may be etched.

In addition, the processing pressure in this step is made to be lower than the processing pressure in the above-described first CLN step S50. This allows the film formed in the entire reaction tube 203 including the low temperature region L of the reaction tube 203 to be etched.

In addition, the supply time of the second CLN gas in this step is made to be longer than the supply time of the first CLN gas in the above-described first CLN step S50. This allows the film formed in the entire process chamber 201 including the low temperature region L to be etched in this step.

In addition, the processing temperature in this step is made to be lower than the processing temperature in the above-described first CLN step S50. This allows the internal temperature of the process chamber 201 to be uniform.

That is, in a case where the cumulative film thickness in the reaction tube 203 is smaller than the first predetermined value, the next substrate processing is performed. Then, when the cumulative film thickness becomes equal to or greater than the first predetermined value, the first CLN process is performed in a short time, and then the substrate processing is performed. In addition, in a case where the cumulative film thickness becomes equal to or greater than the second predetermined value that is greater than the first predetermined value, the second CLN process is performed. This allows CLN to be performed efficiently in a shorter time than a case where the above-described first CLN process is not performed.

The first CLN gas and the second CLN gas use different CLN gases. This allows the CLN targets to be different. That is, selective etching may be performed.

Then, after the second CLN step S60 is performed, the pre-coating step S10 is performed to form a film P in the reaction tube 203. That is, the inside of the reaction tube 203 is pre-coated.

### (3) Effects of the Present Embodiment

According to the embodiments of the present disclosure, one or more effects set forth below may be achieved.
(a) By performing the first CLN step which performs CLN in a short time depending on the cumulative film thickness of the deposited film deposited in the process container, it is possible to shorten the time for CLN.
(b) In addition, by performing the first CLN step or the second CLN step depending on the cumulative film thickness of the deposited film deposited in the process container, it is possible to shorten the time for CLN compared to a case where the first CLN step is not performed, thereby improving the productivity.
(c) In addition, by performing the first CLN step, a portion of the film formed in the process container is left to maintain the impermeable state in the process container, making it possible to reduce temperature changes in the process container and facilitate temperature control.
(d) In addition, by using different CLN gases as the first CLN gas and the second CLN gas, it is possible to perform selective etching.
(e) In addition, by forming the film P different from the film formed on the wafer in the film-forming step, it is possible to perform etching by using a selectivity.
(f) In addition, by performing the pre-coating step after the second CLN step is performed, it is possible to reduce the surface roughness of the initial film in the film P. In addition, it is possible to suppress the film thickness drop phenomenon from occurring in the next film-forming step. Further, it is possible to adjust the environment and the state in the process container for the next film-forming step.

### (4) Other Embodiments

The embodiments of the present disclosure are specifically described above. However, the present disclosure is not limited to the above-described embodiments, and various modifications may be made without departing from the gist of the present disclosure.

For example, in the above-described embodiments, a case where the target film of CLN, which is the film formed in the film-forming step S20, is a TiN film is described as an example. However, the present disclosure is not limited thereto. The embodiments of the present disclosure may be used even in a case where the target film of CLN is, for example, a film containing at least one element selected from the group of Si, Al, Ti, Zr, Hf, Mo, W, Co, Ni, and the like. These embodiments may also obtain the same effects as the above-described embodiments.

In addition, in the first determination step S30 in the above-described embodiments, for example, the film thickness of the product substrate may be used as the first predetermined value. That is, the first CLN step may be performed every time the processing of the product substrate is started. These embodiments may also obtain the same effects as the above-described embodiments.

Recipes used in each process may be provided individually according to the processing contents and may be recorded and stored in the memory 121c via a telecommunication line or the external memory 123. Moreover, at the beginning of each process, the CPU 121a may properly select an appropriate recipe from the recipes recorded and stored in the memory 121c according to the processing contents. Thus, it is possible to form films of various kinds, composition ratios, qualities, and thicknesses with enhanced reproducibility in a single substrate processing apparatus. Further, it is possible to reduce an operator's burden and to quickly start each process while avoiding an operation error.

The recipes mentioned above are not limited to newly-provided ones but may be provided, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the existing substrate processing apparatus may be directly modified by operating the input/output device 122 of the substrate processing apparatus.

An example in which a film is formed by using a batch-type substrate processing apparatus configured to process a plurality of wafers 200 at a time is described in the above-described embodiments. The present disclosure is not limited to the above-described embodiments, but may be appropriately applied, for example, to a case where a film is formed by using a single-wafer type substrate processing apparatus configured to process a single substrate or several substrates at a time. In addition, an example in which a film is formed by using a substrate processing apparatus provided with a hot-wall-type process furnace is described in the above-described embodiments. The present disclosure is not limited to the above-described embodiments, but may be appropriately applied to a case where a film is formed by using a substrate processing apparatus provided with a cold-wall-type process furnace.

Even in the case of using these substrate processing apparatuses, each process may be performed according to processing procedures and process conditions which are the same as those in the above-described embodiments and other embodiments, and effects which are the same as those of the above-described embodiments and other embodiments may be obtained.

In addition, the above-described embodiments and other embodiments may be used in proper combination. Processing procedures and process conditions used in this case may be the same as, for example, the processing procedures and process conditions in the above-described embodiments and other embodiments.

According to the present disclosure in some embodiments, it is possible to shorten a time for cleaning.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) processing the substrate in a process container; and
(b) a first cleaning of cleaning an inside of the process container,
wherein in (b), the act of cleaning is performed with a first cleaning condition that is set based on a thickness of a film formed in the process container in (a).

2. The method of claim 1, wherein the first cleaning condition is a condition in which an amount of the film that is etched is less than an amount of the film corresponding to the thickness.

3. The method of claim 1, further comprising (c) estimating the thickness of the film each time (a) is performed.

4. The method of claim 3, wherein the thickness of the film is calculated based on at least one selected from the group of a processing time, a number of times the substrate is processed, a flow rate of a gas used when the substrate is processed, and an internal pressure of the process container.

5. The method of claim 3, further comprising (d) performing (a) after performing (b) when the thickness of the film is equal to or greater than a first predetermined value.

6. The method of claim 5, further comprising:
(e) setting a second cleaning condition such that another film with a thickness equal to or greater than the thickness of the film in (a) is etched when the thickness of the another film is equal to or greater than a second predetermined value that is greater than the first predetermined value; and
(f) a second cleaning of cleaning the inside of the process container based on the second cleaning condition.

7. The method of claim 6, wherein in (e), the second cleaning condition is set such that a pre-coating film formed in the process container is also etched.

8. The method of claim 7, further comprising (g) pre-coating the inside of the process container after (f).

9. The method of claim 1, further comprising forming a pre-coating film in the process container before (a).

10. The method of claim 9, wherein the pre-coating film is a film different from the film formed on the substrate in (a).

11. The method of claim 9, wherein in (b), the film formed in (a) is etched and the pre-coating film is not etched.

12. The method of claim 1, wherein in (b), a film formed in a product region of the process container is etched.

13. The method of claim 5, wherein in (b), a film formed in a product region of the process container is etched, and
wherein in (d), a film formed in an entire region of the process container is etched.

14. The method of claim 5, wherein in (b), a film formed in a high temperature region of the process container is etched, and
wherein in (d), a film formed in a low temperature region of the process container is etched.

15. The method of claim 5, wherein in (b) and (d), different cleaning gases are used.

16. The method of claim 14, wherein in (b), at least one selected from the group of a NF₃ gas, a F₂ gas, a Cl₂ gas, and a HF gas is used, and
wherein in (d), at least one selected from the group of a NF₃ gas, a F₂ gas, a Cl₂ gas, a Br₂ gas, a BCl₃ gas, and a ClF₃ gas is used.

17. A method of manufacturing a semiconductor device, comprising the method of claim 1.

18. A non-transitory computer-readable recording medium storing a program that causes, by a computer, a substrate processing apparatus to perform a process comprising:
(a) processing a substrate in a process container; and
(b) a first cleaning of cleaning an inside of the process container,
wherein in (b), the act of cleaning is performed with a first cleaning condition that is set based on a thickness of a film formed in the process container in (a).

19. A substrate processing apparatus comprising:
a process container; and
a controller configured to be capable of performing a control to perform a process including:
(a) processing a substrate in the process container; and
(b) a first cleaning of cleaning an inside of the process container,
wherein in (b), the act of cleaning is performed with a first cleaning condition that is set based on a thickness of a film formed in the process container in (a).
